(19) United States
(12) Patent Application Publication
(10) Pub. No.: US 2007/0238254 A1
(43) Pub. Date: Oct. 11, 2007

(54) Method of etching low dielectric constant films

(75) Inventor: Christopher N. Ordonio, San Jose, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/390,648

(22) Filed: Mar. 28, 2006

(51) Int. Cl. H01L 21/336

(52) U.S. Cl. 438/301

(57) ABSTRACT

A method for etching a low dielectric material to form sidewall spacers including forming a gate electrode on a substrate, forming a source region and a drain region disposed in a substrate, forming a low dielectric constant film over the gate electrode, source region, and drain region, and etching the low dielectric constant film to form sidewall spacers. The method also includes a first part of the etch process that has a lower oxygen flow rate and a higher power substrate bias than a second part of the etch process. Etching the low dielectric constant film includes exposing the substrate to carbon tetrafluoride, oxygen, nitrogen, and argon.

### BACKGROUND OF THE INVENTION

1. Field of the Invention

Embodiments of the present invention generally relate to a method for semiconductor processing. More specifically, embodiments of the present invention relate to a method for forming spacers with low dielectric constants.

2. Description of the Related Art

Ultra-large-scale integrated (ULSI) circuits often include more than one million transistors on a semiconductor substrate which cooperate to perform various functions within an electronic device. ULSI circuits may include complementary metal-oxide-semiconductor (CMOS) field effect transistors.

A CMOS transistor includes a gate structure that is located between a source region and a drain region in a semiconductor substrate. The gate structure (stack) generally includes a gate electrode formed on a gate dielectric material. The gate electrode controls a flow of charge carriers beneath the gate dielectric in a channel region that is formed between the drain region and the source region. Typically a spacer layer disposed proximate the gate stack forms a sidewall on either side thereof. Sidewall spacers serve several functions, including electrically isolating the gate electrode from source and drain contacts or interconnects, protecting the gate stack from physical degradation during subsequent processing steps, and providing an oxygen and moisture barrier to protect the gate metal. One example of a sidewall spacer arrangement is disclosed in U.S. patent application Ser. No. 10/397,776, filed Mar. 25, 2003, which is incorporated by reference herein.

A conventional gate stack is formed from materials having dielectric constant of less than about 5 and is typically protected by a silicon nitride spacer. Further reduction in transistor sizes requires gate layers having dielectric constants of greater than 10. If the sidewall spacer is fabricated from a relatively high dielectric constant material, such as above 7, for example, silicon nitride, excessive signal crosstalk between adjacent interconnection lines can occur in the completed gate electrode. While ultra-low dielectric constant materials, such as materials with constants below 3, may be employed as a spacer layer, these materials lack the necessary structural integrity to survive subsequent processing steps and the oxygen and moisture imperviousness required to protect the gate metal from corrosion.

In addition, conventional thermal chemical vapor deposition (CVD) processes used to prepare silicon nitride spacers require high deposition temperatures, typically warmer than 600° C. A silicon nitride spacer deposited at high temperature has very good conformality, such as about 95 percent. However, the high deposition temperature requires a large thermal cycle for the gate device and is not compatible with advanced device manufacturing for 0.09 micron technology and beyond.

Therefore, there is a need for low dielectric constant sidewall spacers for low dielectric constant gate stacks that can be deposited at low temperature and that possess the desired physical properties of structural stability and hermeticity. An etch method to provide acceptable spacers is needed.

### SUMMARY OF THE INVENTION

The present invention generally provides a method for etching a low dielectric material to form sidewall spacers including forming a gate electrode on a substrate, forming a source region and a drain region disposed in a substrate, forming a low dielectric constant film over the gate electrode, source region, and drain region, and etching the low dielectric constant film to form sidewall spacers. The method also includes a first part of the etch process that has a lower oxygen flow rate and a higher power substrate bias than a second part of the etch process. Etching the low dielectric constant film includes exposing the substrate to carbon tetrafluoride, oxygen, nitrogen, and argon.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional view of a PECVD chamber.

FIG. 2 is a sectional view of an etch chamber.

FIGS. 3A-3H are schematic views of a formed feature as it undergoes processing.

### DETAILED DESCRIPTION

The present invention provides a sidewall spacer with a low dielectric constant and an etching method for forming the spacer provides a spacer with desirable low dielectric constant properties.

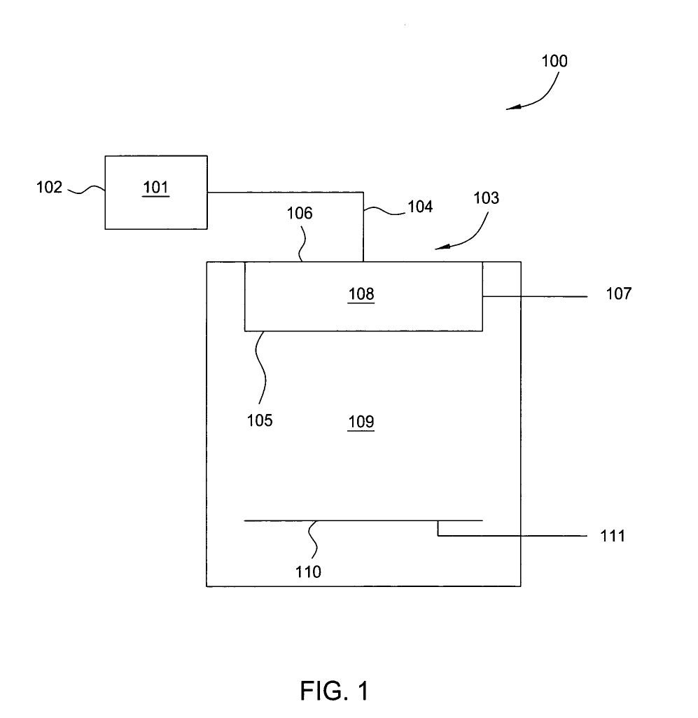

FIG. 1 is a sectional view of a PECVD chamber assembly 100. The PECVD chamber may be any plasma enhanced CVD chamber such as the CENTURA ULTIMA HDP-CVD™ chamber, PRODUCER APF PECVD™ chamber, PRODUCER BLACK DIAMOND™ chamber, PRODUCER BLOK PECVD™ chamber, PRODUCER DARC PECVD™ chamber, PRODUCER HARP™ chamber, PRODUCER PECVD™ chamber, PRODUCER STRESS NITRIDE PECVD™ chamber, and PRODUCER TEOS FSG PECVD™ chamber, available from Applied Materials, Inc. of Santa Clara, Calif. The chamber assembly 100 has a gas source 102 to provide precursor gases to a remote plasma source 101. The remote plasma source 101 is connected to the gas distribution assembly 103 by a conduit 104. The gas distribution assembly 103 includes a chamber lid 106 and a gas distribution plate 105 that form a gas processing region 108. The lid 106 and /or gas distribution plate 105 may be connected to a power source 107. A substrate support 110 in the base of a chamber processing region 109 is also connected to a power source 111. Thus, plasma may be formed in the remote plasma source 101, in the gas processing region 108, and/or in the processing region 109.

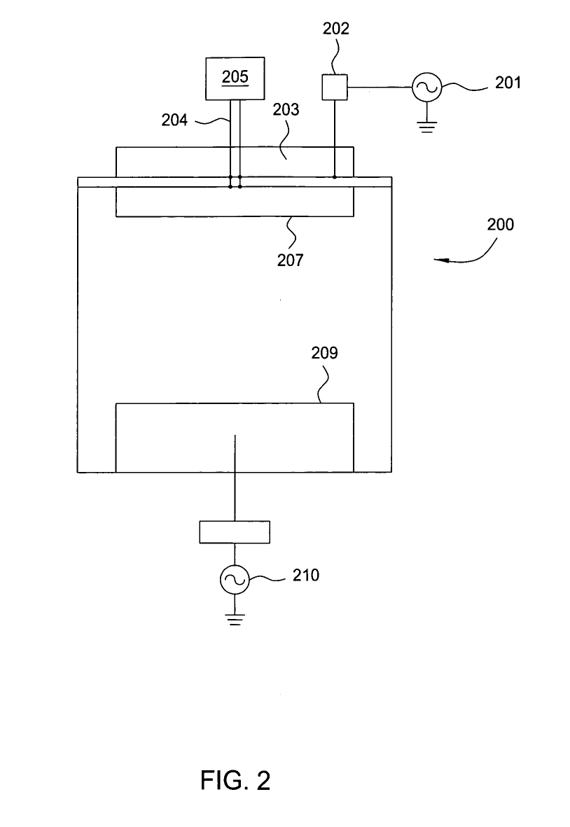

FIG. 2 is a sectional view of an etch chamber 200. The etch chamber 200 may be any etch chamber such as the CENTURA ADVANTEDGE SILICON ETCH™ chamber, CENTURA ADVANT EDGE METAL ETCH™ chamber, CENTURA EMAX ETCH™ chamber, CENTURA ENABLER ETCH™ chamber, CENTURA HART ETCH™ chamber, CENTURA TRANSFORMA ETCH™ chamber, and PRODUCER ETCH™ Chamber, all available from Applied Materials, Inc. of Santa Clara, Calif. The etch chamber 200 has a power source 201 with a controller 202 that provides power to a plasma generator 203. The plasma generator 203 may be a toroidal, inductive, or capacitive plasma source and may include a magnetic coil (not shown). The chamber lid 204 is configured to provide plasma or energy from the plasma generator 203 and gas from the process gas source through gas conduit 206. A gas distribution plate 207 may be attached to the chamber lid 204 or chamber sidewalls 208. The base of the chamber 200 contains a substrate support 209 which is attached to a power source 210.

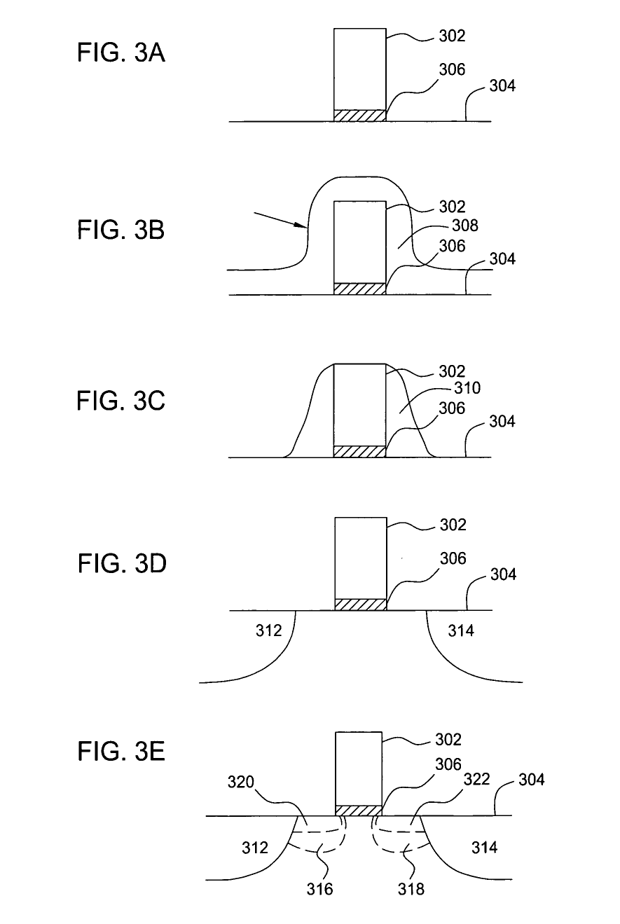

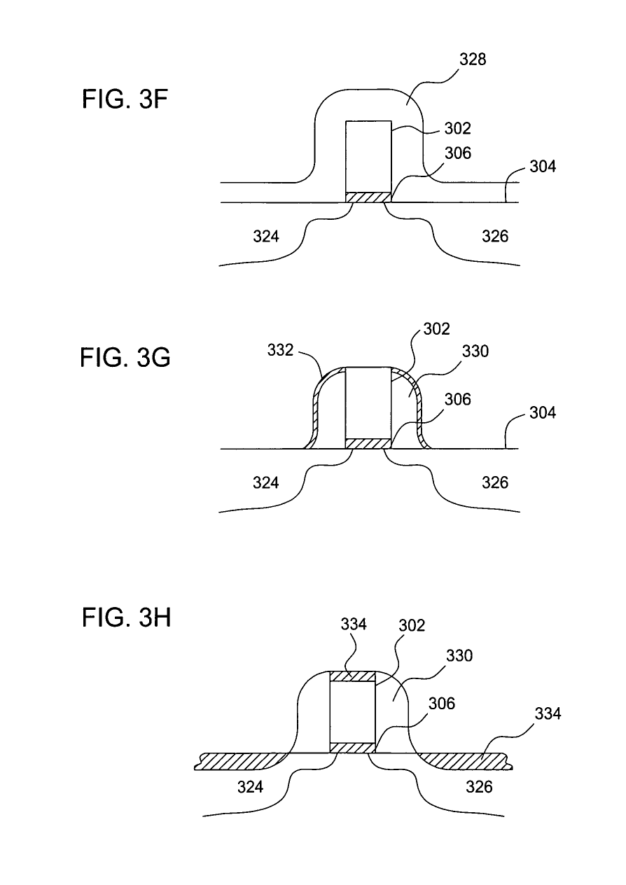

FIGS. 3A-3H are schematic views of a formed feature as it undergoes processing. Additional process information is available in United States Patent Application No. XXXXXX (APPM 10133), filed XXX, and titled “Low K Spacer Integration into CMOS Transistors,” which is incorporated by reference herein. FIG. 3A is a sectional view of a feature with a gate electrode 302 with a gate oxide layer 306 formed on a substrate 304. Substrates on which embodiments of the invention may be useful include, but are not limited to, crystalline silicon (e.g., Si<100> or Si<111>), silicon oxide, silicon germanium, doped or undoped polysilicon, doped or undoped silicon, and silicon nitride. Other substrates may include bare silicon wafers, or substrates having conductive or non-conductive layers thereon, such as layers comprising materials having dielectric, conductive, or barrier properties, including aluminum oxide and polysilicon, and pretreated surfaces. Pretreatment of surfaces may include one or more of polishing (e.g., CMP, electro-polishing), patterning, etching, reduction, oxidation, hydroxylation, annealing and baking. The term substrate surface is used herein to include any semiconductor feature, including the exposed surfaces of interconnect features, such as the top, bottom, and/or side walls of vias, lines, dual damascenes, contacts and the like.

FIG. 3B illustrates a conformal dielectric film 308 formed on the gate electrode 302 and substrate 304. The film may be formed in a PECVD chamber such as the chamber illustrated by FIG. 1 above. The dielectric film 308 may be an amorphous carbon film. Amorphous carbon film deposition is described in U.S. Pat. No. 6,541,397, issued Apr. 1, 2003 which is incorporated by reference herein. Additional details are described in U.S. patent application Ser. No. 11/065,464, filed Feb. 24, 2005, and titled, “Liquid Precursors for the CVD Deposition of Amorphous Carbon Films,” which is incorporated by reference herein.

FIG. 3C is a sectional view of the conformal dielectric film 308 which has been etched to form sidewall spacers 310. Conformal dielectric film 308 is etched in a PECVD or etch chamber such as the chambers illustrated by FIGS. 1 and 2 above. Conventional etching techniques may be used to form the sidewall spacers 310. Exemplary conventional etching techniques are described in U.S. patent application Ser. No. 10/612,642, filed Jul. 1, 2003, which is incorporated by reference herein.

FIG. 3D is a sectional view of the gate electrode 302 with a gate oxide layer 306 formed on a substrate 304. An ion implant process forms source region 312 and drain region 314 in the region adjacent the sidewall spacers 310 by implanting dopants into the substrate 304. The sidewall spacers 310 are removed by a stripping process and/or by a process using oxidizing plasma. A rapid thermal anneal process is performed to activate the dopants in the source and drain regions 312 and 314. Rapid thermal anneal processes are described in U.S. patent application Ser. No. 11/245,758, filed on Oct. 7, 2005, and titled, “Apparatus and Method for the Deposition of Silicon Nitride Films,” which is incorporated by reference herein.

FIG. 3E is a sectional view of the feature with (halo) implant regions 316, 318, 320, and 322. The implant regions 316, 318, 320, and 322 are formed by rapid thermal anneal, ion implant, absorptive material deposition, laser anneal, and stripping or ashing to remove the absorptive material processes. The regions 312, 316, and 320 blend together as the processing steps are performed. Similarly, regions 314, 318, and 322 blend together.

FIG. 3F is a sectional view of the feature with source region 324 and drain region 326. A low dielectric constant material 328 is conformally deposited over the gate electrode 302 with a gate oxide layer 306 formed on a substrate 304. Low dielectric constant films that may be used as low dielectric constant material 328 include silicon containing and optionally oxygen and/or carbon containing films, such as silicon carbide, oxygen doped silicon carbide, nitrogen doped silicon carbide, carbon doped silicon nitride, carbon doped silicon oxide, nitrogen doped silicon oxycarbide, and combinations thereof. Detailed discussion of low dielectric constant materials for sidewall spacers including deposition methods is described in U.S. patent application Ser. No. 11/032,859, filed on Jan. 10, 2005, titled, “Method for Producing Gate Stack Sidewall Spacers,” which is incorporated by reference herein.

FIG. 3G illustrates sidewall spacers 330 with surfaces 332 that have undergone surface treatment. The sidewall spacers 330 are etched by using a two part process. The process is carried out in a PECVD or etch chamber, such as those described above for FIGS. 1 and 2. Preferably, the CENTURA ENABLER ETCH™ chamber is used. The first part of the etch process delivers to the chamber about 100 to about 300 sccm carbon tetrafluoride (CF₄), about 10 to about 50 sccm oxygen (O₂), about 30 to about 100 sccm nitrogen (N₂), and about 100 to about 300 sccm argon (Ar). The ratio of carbon tetrafluoride to oxygen in the gas mixture is about 10:about 1. The chamber pressure is about 10 mTorr and the chamber bias is about 90 W. The neutral species tuning unit, which is a ratio for changes to the center to edge flux flow, is set to 1. The charged species tuning unit, which controls a magnetic coil to enhance plasma density, is set to 2. The first part of the etch process should continue for about 35 seconds, depending on the thickness of the film.

The second part of the etch process delivers slightly more oxygen at lower power. The gas mixture includes about 100 to about 300 sccm carbon tetrafluoride (CF₄), about 50 to about 100 sccm oxygen (O₂), about 30 to about 100 sccm nitrogen (N₂), and 100 to 150 sccm argon (Ar). The chamber pressure is about 10 mTorr and the chamber bias is about 70 W. The neutral species tuning unit, which is a ratio for changes to the center to edge flux flow, is set to 1. The charged species tuning unit, which controls a magnetic coil to enhance plasma density, is set to 2. The second part of the etch process should continue for about 14 seconds. The optimum ratio of carbon tetrafluoride to oxygen in the gas mixture is about 5:about 1.

Surface treatment for surfaces 332 for sidewall spacers 330 is performed to seal the surface to prevent dopant diffusion. A thin layer of silicon oxide may be deposited.

FIG. 3H illustrates gate electrode 302 and source and drain regions 324 and 326 with an upper silicide layer 334. The upper silicide layer 334 is a conductive material such as a metal or metal alloy and/or silicon.

Experimental testing of the etch process illustrated by FIGS. 3A-3H results in sidewalls that are not over etched or under etched. Scanning electron micrographs of the formed features show improved conformality. A reduction in low dielectric constant material across the fields of the substrate was also illustrated by the micrographs. The profiles of the low dielectric constant films were comparable to the profiles of higher dielectric constant materials such as silicon nitride or silicon nitride.

While the foregoing is directed to embodiments of the present invention, other and further embodiments of the invention may be devised without departing from the basic scope thereof, and the scope thereof is determined by the claims that follow.

1. A method for etching a low dielectric material to form sidewall spacers, comprising:
forming a gate electrode on a substrate;
forming a source region and a drain region disposed in the substrate;
forming a low dielectric constant film over the gate electrode, source region, and drain region; and
etching the low dielectric constant film to form sidewall spacers.

2. The method of claim 1, wherein the etching the low dielectric constant film comprises exposing the substrate to carbon tetrafluoride, oxygen, nitrogen, and argon.

3. The method of claim 1, wherein the etching the low dielectric constant film comprises exposing the substrate to a two part etch process and a first part of the etch process has a lower oxygen flow rate than a second part of the etch process.

4. The method of claim 3, wherein the oxygen flow rate of the first part of the etch process is about 10 sccm to about 50 sccm.

5. The method of claim 3, wherein the oxygen flow rate of the second part of the etch process is about 50 to about 100 sccm.

6. The method of claim 3, wherein the first part of the etch process has a higher substrate bias than the second part of the etch process.

7. The method of claim 6, wherein the first part of the etch process has a substrate bias that is about 90 W.

8. The method of claim 6, wherein the second part of the etch process has a substrate bias that is about 70 W.

9. The method of claim 3, wherein the first part of the etch process occurs for about 35 seconds and the second part of the etch process occurs for about 14 seconds.

10. The method of claim 1, wherein the etching the low dielectric constant film comprises exposing the substrate to about 100 to about 300 sccm carbon tetrafluoride (CF₄), about 10 to about 50 sccm oxygen (O₂), about 30 to about 100 sccm nitrogen (N₂), and about 100 to about 300 sccm argon (Ar).

11. The method of claim 1, wherein the etching the low dielectric constant film is performed at about 10 mTorr.

12. A method for etching a low dielectric material to form sidewall spacers, comprising:
forming a gate electrode on a substrate;
forming a source region and a drain region disposed in a substrate;
forming a low dielectric constant film over the gate electrode, source region, and drain region; and
etching the low dielectric constant film to form sidewall spacers, wherein the etching is a two part process with a first part and a second part of the etching of the low dielectric constant film.

13. The method of claim 12, wherein the low dielectric constant film comprises silicon carbide, oxygen doped silicon carbide, nitrogen doped silicon carbide, carbon doped silicon nitride, nitrogen doped silicon oxycarbide, and combinations thereof.

14. The method of claim 12, wherein first part of the etch process has a lower oxygen flow rate and a higher power substrate bias than a second part of the etch process.

15. The method of claim 12, wherein the etching the low dielectric constant film comprises exposing the substrate to carbon tetrafluoride, oxygen, nitrogen, and argon.

16. The method of claim 12, wherein the oxygen flow rate of the first part of the etch process is about 10 sccm to about 50 sccm.

17. The method of claim 16, wherein the oxygen flow rate of the second part of the etch process is about 50 sccm to about 100 sccm.

18. The method of claim 12, wherein the first part of the etch process has a substrate bias that is about 90 W.

19. The method of claim 18, wherein the second part of the etch process has a substrate bias that is about 70 W.

20. The method of claim 18, wherein the etching the low dielectric constant film is performed at about 10 mTorr.
